(19) United States
(12) Patent Application Publication
(10) Pub. No.: US 2011/0207257 A1
(43) Pub. Date: Aug. 25, 2011

(54) MANUFACTURING METHOD FOR A SOLID-STATE IMAGE PICKUP DEVICE

(75) Inventor: Manjirou WATANABE, Saitama-shi (JP)

(73) Assignee: FUJIFILM CORPORATION, Tokyo (JP)

(21) Appl. No.: 12/979,205

(22) Filed: Dec. 27, 2010

(30) Foreign Application Priority Data
Feb. 25, 2010 (JP) 2010-040638

(51) Int. Cl. H01L 31/18

(52) U.S. Cl. 438/66; 257/E31.001; 257/E31.11

(57) ABSTRACT

Provided is a manufacturing method for a solid-state image pickup device, which enables easily manufacturing a thin-type solid-state image pickup device at a wafer level. A support substrate is bonded to a cover glass substrate. A surface of the cover glass substrate on an opposite side to the support substrate is mechanically polished. A part of the support substrate is removed, and a plurality of frame-shaped spacers are formed on the cover glass substrate. The cover glass substrate is made thinner by wet etching so as to have a predetermined thickness. The cover glass substrate and a silicon wafer on which solid-state image pickup elements are formed are attached to each other via the spacers. The cover glass substrate is divided into individual pieces. The silicon wafer is divided into individual pieces. In this way, the solid-state image pickup device is manufactured.

### BACKGROUND OF THE INVENTION

1. Field of the Invention

The presently disclosed subject matter relates to a manufacturing method for a solid-state image pickup device, and more particularly, to a manufacturing method for a thin-type solid-state image pickup device.

2. Description of the Related Art

Against a backdrop of a recent demand for downsizing of devices such as a digital camera and a portable phone, a solid-state image pickup device which is formed of a CCD or a CMOS used in the digital camera and the portable phone is increasingly required to be downsized. Therefore, a shift is being made from a large-sized package in which an entire solid-state image pickup element chip is hermetically sealed to a small-sized package (chip size package: CSP) having a size substantially equal to that of a solid-state image pickup element chip.

There has been proposed a method of manufacturing, collectively on a wafer basis (wafer level), a solid-state image pickup device of the CSP type in which a light receiving part of a solid-state image pickup element is hermetically sealed by a permeable flat plate and a spacer (Japanese Patent Application Laid-Open Nos. 2002-231919 and 2001-351997).

### SUMMARY OF THE INVENTION

The solid-state image pickup device is increasingly required to be made further thinner. On the other hand, in the case where a thin-type solid-state image pickup device is manufactured at the wafer level as described above, the following problem arises.

In order to obtain the thin-type solid-state image pickup device, it is necessary to make thinner a permeable substrate which is a main constituent member thereof. A glass substrate is most appropriate for the permeable flat plate in terms of hermetical sealing. However, the rigidity of the glass substrate becomes lower as the glass substrate is made thinner. Therefore, the glass substrate sags under its own weight, and becomes prone to breakage state, which leads to difficult handling.

Particularly in the case where the glass substrate has a size φ (diameter) more than 8 inches, such influence is remarkable. It is extremely difficult to adopt a complicated process for forming a large number of spacers with the use of the thin glass substrate having a reduced rigidity.

The presently disclosed subject matter has been made in view of the above-mentioned circumstances, and therefore has an object to provide a method of stably manufacturing a high-quality thin-type solid-state image pickup device at the wafer level.

In order to achieve the above-mentioned object, a manufacturing method for a solid-state image pickup device of the presently disclosed subject matter includes: bonding a support substrate to a cover glass substrate; mechanically polishing a surface of the cover glass substrate on an opposite side to the support substrate; removing a part of the support substrate, and forming a plurality of frame-shaped spacers on the cover glass substrate; thinning the cover glass substrate by wet etching so as to have a predetermined thickness; attaching the cover glass substrate and a semiconductor substrate on which solid-state image pickup elements are formed, to each other via the spacers; dividing the cover glass substrate into individual pieces; and dividing the semiconductor substrate into individual pieces.

According to the presently disclosed subject matter, the cover glass substrate and the support substrate are handled in a bonded state, and the cover glass substrate is mechanically polished. This makes it possible to prevent breakage during an operation in which a load is applied to the cover glass substrate. The cover glass substrate and the support substrate are handled in the bonded state, and hence the spacers can be easily formed. In addition, after the formation of the spacers, the cover glass substrate is made thinner by using wet etching. Glass of the cover glass substrate is removed by a chemical reaction, and hence, unlike a method such as mechanical polishing, a load is not applied to the cover glass substrate. Accordingly, it is possible to stably obtain a thin cover glass substrate with the spacers without causing breakage during the operation. In addition, unlike a method of fixing a substrate to a processing table as in mechanical polishing, the use of wet etching makes the thinning operation easier even when the cover glass substrate has irregularities due to the spacers formed on one side thereof.

It has been generally known that, in the case where defects (microcracks and distorted layer) exist on a glass surface, if the glass surface is subjected to wet etching, etching proceeds selectively around the defect portions as reactive points, and eventually, semispherical dents (referred to as dimples, pits, and the like) are formed on the surface. In the case of the solid-state image pickup device, if there are such dents on the cover glass surface, the shade thereof appears on an image, which is a serious problem. In particular, as the solid-state image pickup device is made further thinner and a distance between the cover glass surface and a light receiving part becomes shorter, the shade becomes darker, so that the dents have a larger influence. According to the presently disclosed subject matter, the surface of the cover glass substrate is mirror-finished by mechanical polishing, to thereby remove microcracks and a distorted layer (=dents as reactive points) on a superficial layer. As a result, it is possible to suppress the occurrence of dents on the surface during wet etching.

In the manufacturing method for a solid-state image pickup device of the presently disclosed subject matter, it is preferable that the support substrate be a silicon substrate.

In the manufacturing method for a solid-state image pickup device of the presently disclosed subject matter, it is preferable that the mechanically polishing the surface of the cover glass substrate include making a surface roughness Ra of the cover glass substrate 1 nm or smaller.

It is preferable that the manufacturing method for a solid-state image pickup device of the presently disclosed subject matter, further include forming a masking on the spacers on an opposite side to the cover glass substrate, after the spacers have been formed on the cover glass substrate and before the cover glass substrate is subjected to the wet etching.

In the manufacturing method for a solid-state image pickup device of the presently disclosed subject matter, it is preferable that the forming the spacers on the cover glass substrate include mechanically polishing the support substrate.

In the manufacturing method for a solid-state image pickup device of the presently disclosed subject matter, it is preferable that the bonding the support substrate to the cover glass substrate is performed in a vacuum.

According to the presently disclosed subject matter, it is possible to stably manufacture a high-quality thin-type solid-state image pickup device at the wafer level.

### BRIEF DESCRIPTION OF THE DRAWINGS

FIG. 1 is a perspective view illustrating a solid-state image pickup device;

FIG. 2 is a cross sectional view illustrating the solid-state image pickup device; and

FIGS. 3A to 3K are explanatory views each illustrating a manufacturing method for the solid-state image pickup device according to an embodiment of the presently disclosed subject matter.

### DETAILED DESCRIPTION OF THE PREFERRED EMBODIMENT

Hereinafter, a preferred embodiment of the presently disclosed subject matter is described with reference to the accompanying drawings. Although the presently disclosed subject matter is described by way of the following preferred embodiment, the presently disclosed subject matter can be changed according to various methods without departing from the scope of the presently disclosed subject matter, and embodiments other than the present embodiment can be adopted. Accordingly, all the changes within the scope of the presently disclosed subject matter are encompassed in the scope of the claims for patent. In addition, in this specification, a numerical value range represented by using “to” means a range including numerical values given before and after “to”.

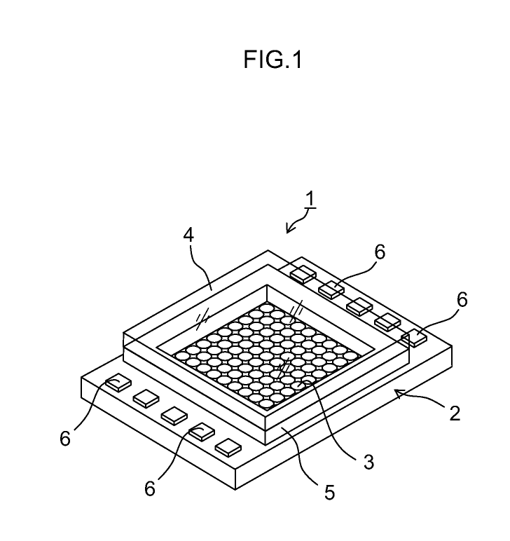

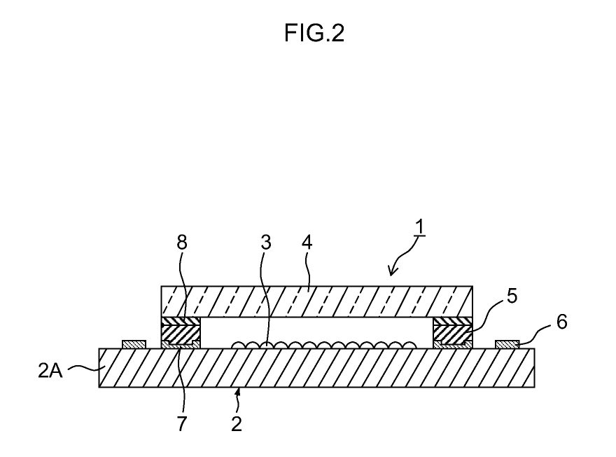

FIG. 1 and FIG. 2 are a perspective view and a cross sectional view illustrating an appearance configuration of a solid-state image pickup device, respectively. The solid-state image pickup device 1 includes a solid-state image pickup element chip 2 on which a plurality of solid-state image pickup elements 3 are provided; a frame-shaped spacer 5 which is attached on the solid-state image pickup element chip 2 and surrounds the plurality of solid-state image pickup elements 3; and a cover glass 4 which is attached on the frame-shaped spacer 5 and seals the plurality of solid-state image pickup elements 3.

The solid-state image pickup element chip 2 is obtained by dividing a disk-shaped semiconductor substrate on which the solid-state image pickup elements are manufactured. The cover glass 4 is obtained by dividing a disk-shaped transparent substrate. As illustrated in FIG. 2, the solid-state image pickup element chip 2 includes a rectangular chip substrate 2A, the solid-state image pickup elements 3 formed on the chip substrate 2A, and a plurality of pads (electrodes) 6 which are arranged outside of the solid-state image pickup elements 3 and used for wiring with external elements. A material of the chip substrate 2A is, for example, silicon single crystal, and the thickness thereof is approximately 0.15 to 0.5 mm.

For manufacturing the solid-state image pickup elements 3, a general semiconductor element manufacturing process is adopted. The solid-state image pickup element 3 includes a photodiode serving as a light receiving element, a transfer electrode which transfers an excitation voltage to the outside, a light shielding film having an opening, and an interlayer insulating film. Further, in the solid-state image pickup element 3, an inner lens is formed above the interlayer insulating film, a color filter is formed above the inner lens via an intermediate layer, and a microlens and the like are formed above the color filter via an intermediate layer.

Because the solid-state image pickup element 3 has the structure as described above, light entering from the outside is condensed by the microlens and the inner lens, and the photodiode is irradiated with the condensed light. As a result, an effective aperture ratio is enhanced.

For the cover glass 4, transparent glass having a thermal expansion coefficient close to that of silicon, for example, “Pyrex (registered trademark) glass” is used, and the thickness thereof is, for example, approximately 0.1 to 0.5 mm.

For the frame-shaped spacer 5, an inorganic material whose physical properties such as a thermal expansion coefficient are similar to those of the chip substrate 2A and the cover glass 4 is desirable, and hence, for example, polycrystalline silicon is used. When a part of the frame-shaped spacer 5 having a frame-like shape is viewed in cross section, the width of the cross section is, for example, approximately 0.1 to 0.3 mm, and the thickness thereof is, for example, approximately 0.03 to 0.15 mm. The frame-shaped spacer 5 has one end surface which is bonded to the chip substrate 2A via an adhesive 7, and another end surface which is bonded to the cover glass 4 via an adhesive 8.

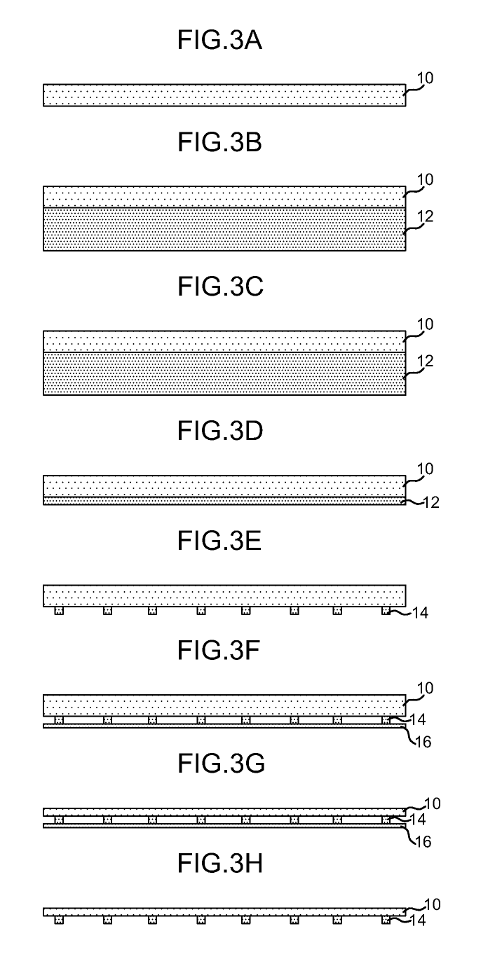

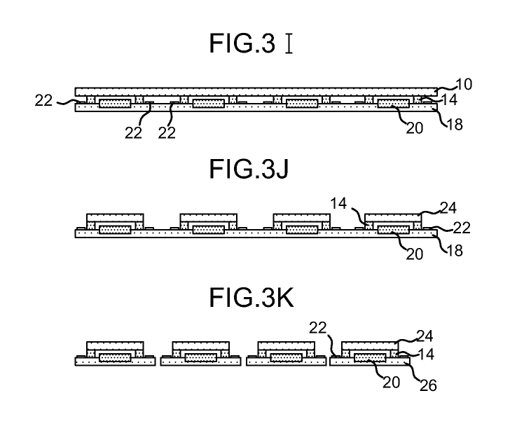

With reference to FIGS. 3A to 3K, description is given of a manufacturing method for the solid-state image pickup device according to the present embodiment. As illustrated in FIG. 3A, a cover glass substrate 10 (for example, a low α-ray glass wafer having an outer diameter φ of 8 inches×a thickness t of 0.3 mm) is prepared. Next, as illustrated in FIG. 3B, a support substrate 12 (for example, a single crystal Si wafer having an outer diameter φ of 8 inches×a thickness t of 0.73 mm) is prepared, and the cover glass substrate 10 and the support substrate 12 are bonded to each other so as to prevent air bubbles and foreign matters from intruding therebetween. The bonding is performed by using an adhesive (UV curing, thermal curing, delayed curing, and the like) or by a direct bonding method such as anodic bonding and surface activated bonding. In order to prevent as far as possible air bubbles from intruding therebetween, it is preferable to bond the cover glass substrate 10 and the support substrate 12 to each other under vacuum.

Next, as illustrated in FIG. 3C, a surface of the cover glass substrate 10 is mirror-finished by mechanical polishing (for example, a lapping process and a polishing process). A polishing amount of the cover glass substrate 10 corresponds to a superficial layer portion including defects. The surface of the cover glass substrate 10 is polished by, for example, a thickness of approximately 0.005 to 0.02 mm. As the mechanical polishing, it is possible to perform one-side polishing in which the support substrate 12 is fixed and only the surface of the cover glass substrate 10 is polished, as well as both-side polishing in which the surface of the cover glass substrate 10 and a surface of the support substrate 12 are polished. That is, both of a both-side polishing apparatus and a one-side polishing apparatus can be selected as an apparatus which performs the mechanical polishing.

In the process of FIG. 3C, the surface of the cover glass substrate 10 is mirror-finished (smoothed) so as to have a roughness (Ra) of 1 nm or smaller. The polishing removes a layer including minute defects on the surface of the cover glass substrate 10 and a layer including minute defects which are caused on the surface of the cover glass substrate 10 during the operation. That is, the cover glass substrate 10 is subjected to the smoothing process after the cover glass substrate 10 and the support substrate 12 have been bonded to each other, and hence it is possible to remove, by the mirror-finishing process, not only the defects existing on the surface of the cover glass substrate 10 itself, but also the defects which are caused on the surface of the cover glass substrate 10 during the bonding process to the support substrate 12 (damages due to a load applied by handling, pressurization, or the like).

When the cover glass substrate 10 is subjected to the mechanical polishing, the cover glass substrate 10 and the support substrate 12 have a total thickness t of 1.03 mm (sum of the thickness of cover glass substrate of 0.3 mm and the thickness of the support substrate of 0.73 mm). This total thickness provides a sufficient rigidity, and hence sagging under their own weight does not occur during the mechanical polishing process and the preceding and subsequent operations, so that the handling thereof can be facilitated.

In general, in the case where the cover glass substrate alone having φ 8 inches is polished, the glass wafer is required to have a thickness t of approximately 0.5 mm in order to stably perform the processing. In the present embodiment, the single crystal Si wafer as the support substrate 12 supports the cover glass substrate 10. Accordingly, even if the thickness t of the cover glass substrate 10 is 0.3 mm, the handling thereof is possible. In addition, the thin cover glass substrate can be used, and hence the cost of members can be suppressed.

Next, as illustrated in FIG. 3D, the support substrate 12 is mechanically polished so as to have a predetermined thickness, for example, thickness t of 0.05 mm. In this process, one-side polishing of only the support substrate 12 is performed. It is preferable that a protection tape be attached to the surface of the cover glass substrate 10 as a shock absorbing member, and then the support substrate 12 be mechanically polished. This is because the protection tape serves to protect the mirror-finished surface of the cover glass substrate 10, and thus prevent defects from being newly caused on the surface of the cover glass substrate 10. It is preferable to use as the protection tape, for example, a back grinding tape used for protecting a patterned surface in a back grinding process of a semiconductor wafer. This is because the back grinding tape is less likely to cause contamination such as residual adhesive.

Next, as illustrated in FIG. 3E, a photolithography technology is applied to the support substrate (patterning of a resist and dry etching), whereby an unnecessary portion of the support substrate is removed. Subsequently, the resist and the adhesive layer are removed by cleaning, so that a large number of frame-shaped spacers 14 are formed. The formation of the spacers 14 is not necessarily limited to the above-mentioned manner. For example, the unnecessary portion of the support substrate 12 may be removed according to a sandblasting method or the like, to thereby form the spacers 14.

Next, as illustrated in FIG. 3F, a masking 16 is formed on the spacers 14 on the opposite side to the cover glass substrate 10. It should be noted that examples of the masking method include: a method of attaching a tape having resistance to hydrofluoric acid to the spacers 14, a method of applying and curing a liquid resin such as an adhesive, and a method of attaching a resin substrate or the like by a double-sided tape.

Next, as illustrated in FIG. 3G, the cover glass substrate 10 with the spacers 14 on which the masking 16 is formed is immersed in an etching solution containing hydrofluoric acid as a major ingredient. The cover glass substrate 10 is immersed in the etching solution until the thickness of the cover glass substrate 10 becomes a predetermined value. The cover glass substrate 10 is made thinner to, for example, t of 0.15 mm. As a result, the cover glass substrate 10 which has a thickness t of 0.15 mm and includes the spacers 14 having a thickness t of 0.05 mm is formed. The surface of the cover glass substrate 10 can be removed without applying a particular external force to the cover glass substrate 10. In this way, the cover glass substrate 10 can be made thinner without being broken during the operation.

It has been known that, in the case where the cover glass substrate is subjected to wet etching, the size (diameter) of dents caused on the cover glass substrate becomes larger in accordance with the scale of originally existing defects and an etching amount (a removal amount of glass). In the present embodiment, the surface roughness Ra of the cover glass substrate 10 is made 1 nm or smaller by the mechanical polishing, whereby the occurrence of dents can be reduced irrespective of the etching amount.

A surface of the cover glass substrate 10 on the spacer 14 side is covered by the masking 16, and thus does not come into contact with the etching solution. Accordingly, only the surface of the cover glass substrate 10 on the opposite side to the spacers 14 is removed to make the cover glass substrate 10 thinner. That is, the thinning of the cover glass substrate 10 is performed with the surface thereof on the spacer 14 side being protected, and hence the surface of the cover glass substrate 10 on the spacer 14 side is not deformed or contaminated by the wet etching. It should be noted that it is preferable to adjust an etching rate of the etching solution so that the in-plane thickness of the cover glass substrate 10 is made uniform and the surface thereof is prevented from becoming rough. It is preferable to set the etching rate to 10 μm/sec or smaller.

Minute defects on the surface of the cover glass substrate 10 have been removed in the mirror-finishing process. Therefore, even in the case where the cover glass substrate 10 is subjected to wet etching using the etching solution, a dent is not caused on the surface of the cover glass substrate 10.

Next, as illustrated in FIG. 3H, after the cover glass substrate 10 is made thinner, the masking 16 is removed.

In a process independent of those of FIGS. 3A to 3H, a silicon wafer (φ 8 inches×t 0.3 mm) 18 serving as a semiconductor substrate is prepared. A general semiconductor manufacturing process is adopted, and a plurality of solid-state image pickup elements 20 and a plurality of pads 22 are formed on a surface of the silicon wafer 18.

Next, an adhesive is applied to the spacers 14 on the opposite side to the cover glass substrate 10. As illustrated in FIG. 3I, the cover glass substrate 10 and the silicon wafer 18 are aligned in the directions of X, Y, and θ, and the cover glass substrate 10 and the silicon wafer 18 are bonded to each other. A light receiving area formed of the solid-state image pickup element 20 is housed in each frame-shaped spacer 14.

Next, as illustrated in FIG. 3J, only the cover glass substrate is ground and cut off by using a dicing apparatus or the like. As a result, the cover glass substrate is divided into individual pieces, that is, cover glasses 24. The used grindstone is formed into a shape rectangular in cross section with a width (0.1 to 1.0 mm) necessary to expose the pads 22 on the silicon wafer 18. Settings are made so that the lowermost point of the grindstone passes at a height of 0.02 to 0.03 mm from the surface of the silicon wafer 18, and the cover glass substrate is ground and cut off in both of the X-axis direction and the Y-axis direction.

Lastly, as illustrated in FIG. 3K, the silicon wafer is ground and cut off in both of the X-axis direction and the Y-axis direction by using a thin grindstone. As a result, the silicon wafer is divided into individual pieces, that is, solid-state image pickup element chips 26. In this way, it is possible to manufacture at the wafer level a large number of thin-type solid-state image pickup devices each having a total thickness t of 0.5 mm (glass: t 0.15 mm+spacer: t 0.05 mm+silicon wafer: t 0.3 mm) at the same time.

What is claimed is:

1. A manufacturing method for a solid-state image pickup device, comprising:
bonding a support substrate to a cover glass substrate;
mechanically polishing a surface of the cover glass substrate on an opposite side to the support substrate;
removing a part of the support substrate, and forming a plurality of frame-shaped spacers on the cover glass substrate;
thinning the cover glass substrate by wet etching so as to have a predetermined thickness;
attaching the cover glass substrate and a semiconductor substrate on which solid-state image pickup elements are formed, to each other via the spacers;
dividing the cover glass substrate into individual pieces; and
dividing the semiconductor substrate into individual pieces.

2. The manufacturing method for a solid-state image pickup device according to claim 1, wherein the support substrate is a silicon substrate.

3. The manufacturing method for a solid-state image pickup device according to claim 1, wherein the mechanically polishing the surface of the cover glass substrate includes making a surface roughness Ra of the cover glass substrate 1 nm or smaller.

4. The manufacturing method for a solid-state image pickup device according to claim 1, further comprising
forming a masking on the spacers on an opposite side to the cover glass substrate, after the spacers have been formed on the cover glass substrate and before the cover glass substrate is subjected to the wet etching.

5. The manufacturing method for a solid-state image pickup device according to claim 1, wherein the forming the spacers on the cover glass substrate includes mechanically polishing the support substrate.

6. The manufacturing method for a solid-state image pickup device according to claim 1, wherein the bonding the support substrate to the cover glass substrate is performed in a vacuum.
